(19) United States
(12) Patent Application Publication
(10) Pub. No.: US 2010/0182043 A1
(43) Pub. Date: Jul. 22, 2010

(54) RECONFIGURABLE CIRCUIT DEVICE AND RECEIVING APPARATUS

(76) Inventors: Tatsuya Tetsukawa, Osaka (JP); Kazuhiro Okabayashi, Osaka (JP)

Correspondence Address: MCDERMOTT WILL & EMERY LLP, 600 13TH STREET, NW, WASHINGTON, DC, 20005-3096, US

(21) Appl. No.: 12/663,467

(22) PCT Filed: Sep. 1, 2008
(86) PCT No.: PCT/JP2008/002390

§ 371 Date: Dec. 7, 2009

(30) Foreign Application Priority Data
Nov. 19, 2007 (JP) 2007-299097

(51) Int. Cl. H03K 19/173

(52) U.S. Cl. 326/38

(57) ABSTRACT

A reconfigurable device includes a first control unit (102) for outputting configuration data and accompanying information, a first storing unit (103) for receiving and storing the accompanying information, and a reconfigurable core (104) for receiving the configuration data and reconfiguring a circuit, wherein information in the first storing unit (103) is read by an external device such as a central processing unit (CPU), and thereby, information about a circuit configured in the reconfigurable core (104) is obtained.

### TECHNICAL FIELD

The present invention relates to a reconfigurable circuit device and a receiving apparatus using the reconfigurable circuit device.

### BACKGROUND ART

In recent years, reconfigurable devices as represented by field programmable gate arrays (FPGAs) have been widely used. The reconfigurable device is an integrated circuit which includes a plurality of logic elements and which is capable of performing any function by changing a function of each logic element or the connection state between the logic elements.

In the reconfigurable device as represented by an FPGA, a circuit description for the reconfigurable device is created by a user using, for example, a register transfer level (RTL) and C language; the circuit description is converted into data for realizing the circuit description in the reconfigurable device; and the data is configured in the reconfigurable device so as to use the reconfigurable device. However, once the data is configured in the reconfigurable device, it was impossible for a third party to know about accompanying information, such as the type of the circuit realized in the reconfigurable device and the version of the circuit.

As a solution to this problem, a conventional technique provides means for obtaining information about the circuit configured in the reconfigurable device by an external device, by adding a memory for storing accompanying information, such as version information, within a reconfigurable core of the reconfigurable device, and an interface for accessing the memory from the external of the reconfigurable device (see, for example, PATENT DOCUMENT 1).

### CITATION LIST

### Patent Document

PATENT DOCUMENT 1: Japanese Patent Publication No. 2001-14359

### SUMMARY OF THE INVENTION

### Technical Problem

However, the means for solving the problem according to the conventional technique uses resources of the reconfigurable core. This may result in reduced resources for the circuit to be realized which needs flexibility.

In addition, since accompanying information such as version information is configured in the reconfigurable device, whether or not to perform configuration cannot be decided depending on the accompanying information.

### Solution to the Problem

To solve the above problems, a reconfigurable device according to the present invention includes a first control unit for outputting configuration data and accompanying information, a first storing unit for receiving and storing the accompanying information, and a core for receiving the configuration data and reconfiguring a circuit. It is possible to obtain information about a circuit configured in the reconfigurable core by reading the first storing unit from an external device, such as a CPU.

The reconfigurable device according to the present invention may include a first control unit for outputting configuration data and accompanying information, a first storing unit for receiving and storing the accompanying information, a second storing unit for receiving and storing expected value information, which is data set by a user or a system in which the device of the present invention is included, a first comparing unit for comparing an output of the first storing unit and an output of the second storing unit, a second control unit for receiving an output of the first comparing unit and determining an execution of a reconfiguration based on the output of the first comparing unit, and a reconfigurable core for receiving an output of the second control unit and reconfiguring a circuit.

The reconfigurable device according to the present invention may include a first control unit for outputting configuration data and accompanying information, a first storing unit for receiving and storing the accompanying information, a second storing unit for receiving and storing expected value information, which is data set by a user or a system in which the device of the present invention is included, a first comparing unit for comparing an output of the first storing unit and an output of the second storing unit, a second control unit for receiving an output of the first comparing unit and determining an execution of a read-back operation from a reconfigurable core based on the output of the first comparing unit, and a reconfigurable core for receiving the configuration data, reconfiguring a circuit, and having a read-back function.

A receiving apparatus according to the present invention includes a reconfigurable device of any one of the above reconfigurable devices, and a configuration in which configuration data and accompanying information both on a network are obtained, wherein the reconfigurable device further includes a second comparing unit for comparing accompanying information of configuration data in the reconfigurable device and the accompanying information of the configuration data on the network, and the configuration data in the reconfigurable device is updated according to a result of the comparison by the second comparing unit.

The receiving apparatus according to the present invention may include any one of the above reconfigurable devices, and a storage device connected to the reconfigurable device and having configuration data and accompanying information, wherein the reconfigurable device further includes a second comparing unit for comparing accompanying information of configuration data in the reconfigurable device and the accompanying information of the configuration data stored in the storage device, and the configuration data in the reconfigurable device is updated according to a result of the comparison by the second comparing unit.

### Advantages of the Invention

As described in the above, it is possible to obtain circuit information configured in a reconfigurable device without consuming resources of a reconfigurable core. It is also possible to perform a function, such as control of execution of configuration, depending on accompanying information.

### BRIEF DESCRIPTION OF THE DRAWINGS

FIG. 1 shows a configuration of a reconfigurable device according to Embodiment 1.

FIG. 2 shows a configuration of a first control unit according to Embodiment 1.

FIG. 3 shows a configuration of a reconfigurable device according to Embodiment 2.

FIG. 4 shows a configuration of a second control unit according to Embodiment 2.

FIG. 5 shows another configuration of the second control unit according to Embodiment 2.

FIG. 6 shows a configuration of a reconfigurable device according to Embodiment 3.

FIG. 7 shows a structure of configuration data and accompanying information used in Embodiments 1-3.

FIG. 8 shows another structure of configuration data and accompanying information in Embodiments 1-3.

FIG. 9 shows a method for automatically generating the configuration data and accompanying information used in Embodiments 1-3.

FIG. 10 shows an example of a system in which the reconfigurable devices according to Embodiments 1-3 are used.

FIG. 11 shows a configuration of a digital television system including the reconfigurable device according to Embodiment 1.

### DESCRIPTION OF REFERENCE CHARACTERS

101 Configuration data and accompanying information
102 First control unit
103 First storing unit
104 Reconfigurable core
105 Bus, CPU, etc.

### DESCRIPTION OF EMBODIMENTS

### Embodiment 1

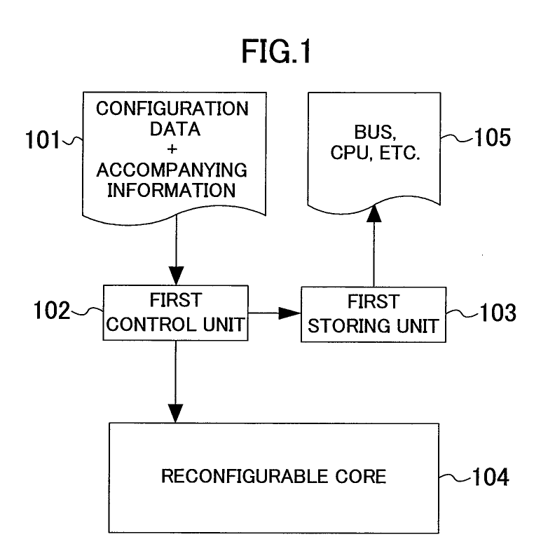

FIG. 1 shows a configuration of a reconfigurable device according to Embodiment 1. The device of FIG. 1 includes a first control unit 102 for receiving configuration data and its accompanying information (for example, version information and date and time of an update) 101, a first storing unit 103 for receiving and holding the accompanying information output from the first control unit 102, and a reconfigurable core 104 for receiving the configuration data output from the first control unit 102 and performing reconfiguration. The first storing unit 103 is connected to a device such as a central processing unit (CPU) directly or via a bus, etc., to allow a memory content to be checked. The first control unit 102 distinguishes the accompanying information from the configuration data, the configuration data and the accompanying information being input to the first control unit 102, and writes the accompanying information in the first storing unit 103. The first control unit 102 outputs the remaining configuration data to the reconfigurable core 104 to reconfigure the reconfigurable core 104. The reference character 105 in FIG. 1 represents a bus, a CPU, etc., to which the first storing unit 103 is connected.

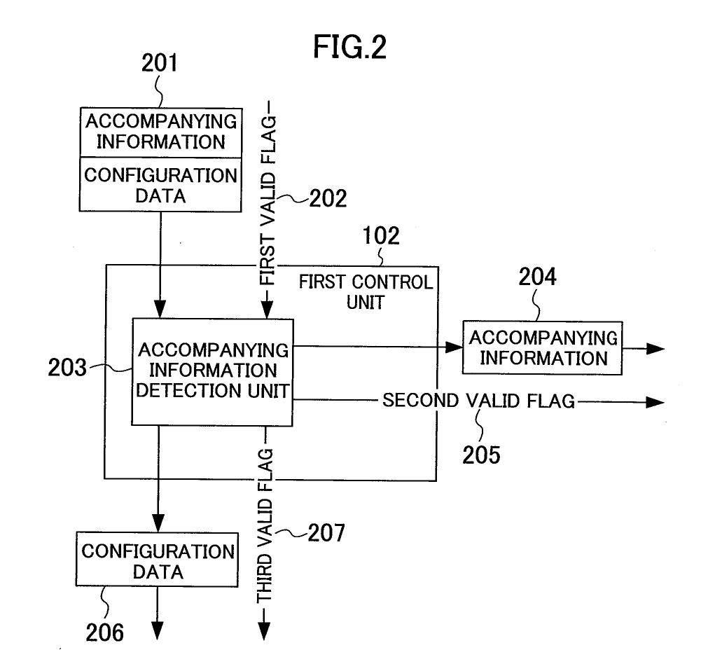

FIG. 2 shows a detailed configuration of the first control unit 102 according to Embodiment 1. The first control unit 102 shown in FIG. 2 receives configuration data and its accompanying information 201 and a first valid flag 202, which is a valid flag of the configuration data and its accompanying information 201, and is constituted by an accompanying information detection unit 203 configured to output accompanying information 204 and its valid flag 205 to the first storing unit 103 and to output configuration data 206 and its valid flag 207 to the reconfigurable core 104.

The accompanying information detection unit 203 detects the accompanying information in predetermined steps, and distinguishes between the configuration data and the accompanying information (the predetermined steps are described later in an example structure of the configuration data and its accompanying information). If the data distinguished by the accompanying information detection unit 203 is accompanying information, the accompanying information 204 is output to the first storing unit 103, and the valid flag 205 is asserted. At this time, invalid data (e.g., data in which all bits are “0”) is output as the configuration data 206 to the reconfigurable core 104, and the valid flag 207 is deasserted. If the data distinguished by the accompanying information detection unit 203 is configuration data, invalid data (e.g., data in which all bits are “0”) is output to the first storing unit 103, and the valid flag 205 is deasserted. At this time, the configuration data portion of the configuration data and its accompanying information 201 is output as the configuration data 206 to the reconfigurable core 104, and the valid flag 207 is asserted. Although the invalid data is described as data in which all bits are “0,” the data that is input to the accompanying information detection unit 203 may be output as it is, or the bits may be arbitrary bits other than “0.” Also, the valid flags 202, 205, and 207 may be a chip select signal, a write enable signal, an address signal, etc. The first valid flag 202 may be a signal for separating the accompanying information and the configuration data from each other.

According to the invention of Embodiment 1, information in the first storing unit 103 is read by an external device, such as a CPU, thereby allowing information about a circuit configured in the reconfigurable core 104 to be obtained from external.

### Embodiment 2

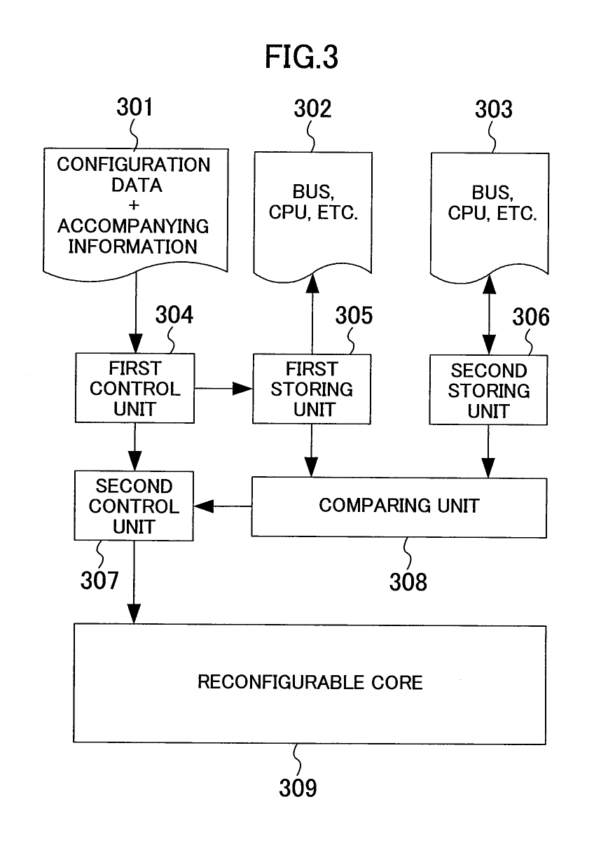

FIG. 3 shows a configuration of a reconfigurable device according to Embodiment 2. The device of FIG. 3 includes: a first control unit 304 for receiving configuration data and its accompanying information (for example, version information and date and time of an update) 301; a first storing unit 305 for receiving and holding the accompanying information output from the first control unit 304; a second storing unit 306 for holding expected value information, which is set by a user or a system in which the device of the present invention is included; a comparing unit 308 for receiving and comparing an output of the first storing unit 305 and an output of the second storing unit 306; a second control unit 307 for receiving an output of the comparing unit 308 and deciding an execution of reconfiguration based on a comparison result; and a reconfigurable core 309 for receiving an output of the second control unit 307 and reconfiguring a circuit. The first storing unit 305 and the second storing unit 306 are connected to devices such as CPUs directly or via busses, and thus, can be accessed from the devices such as CPUs. The reference character 302 in FIG. 3 represents a bus, a CPU, etc., to which the first storing unit 305 is connected, and the reference character 303 represents a bus, a CPU, etc., to which the second storing unit 306 is connected. The devices 302 and 303 to which the first storing unit 305 and second storing unit 306 are connected may be the same devices.

The first control unit 304 in Embodiment 2 is the same as the first control unit 102 in Embodiment 1. The first control unit 304 distinguishes between the configuration data and its accompanying information, which are input in the first control unit 304, and stores the accompanying information in the first storing unit 305. The first control unit 304 outputs the configuration data to the second control unit 307. Accompanying information of the configuration data which the user wishes to configure is set beforehand in the second storing unit 306 from a device such as a CPU. Part or all of the accompanying information stored in the first storing unit 305 and part or all of the accompanying information stored in the second storing unit 306 are compared with each other, and the comparison result is output to the second control unit 307. In FIG. 3, the second storing unit 306 and the comparing unit 308 are illustrated as being implemented through dedicated hardware, but these functions may be implemented through software such as CPUs.

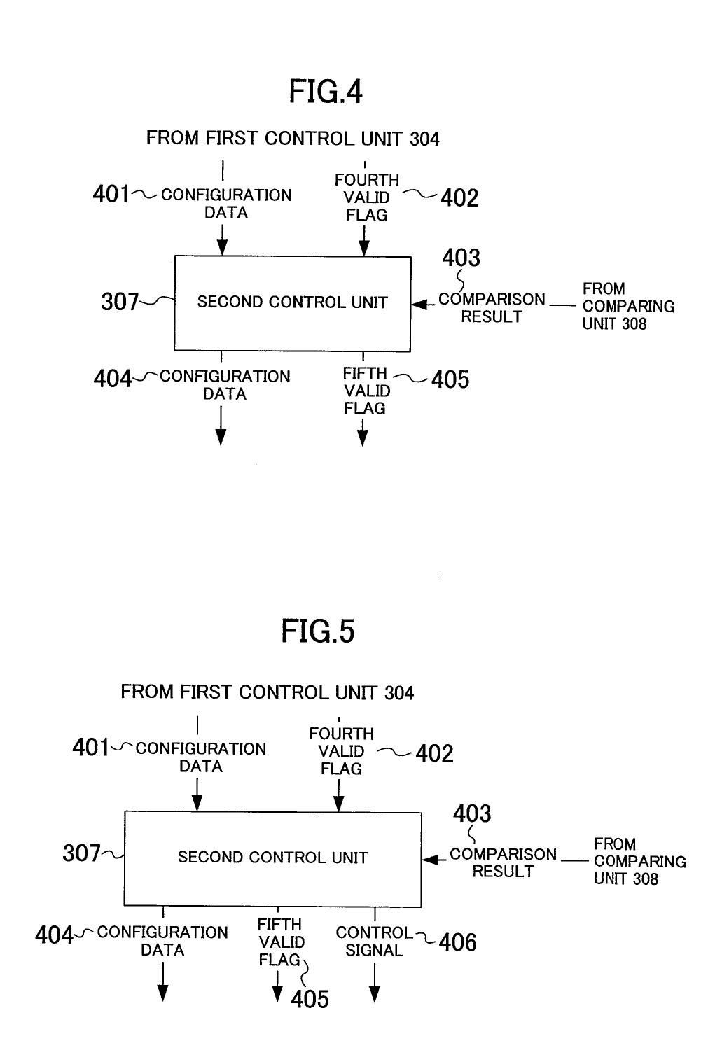

FIG. 4 shows a configuration of the second control unit 307 according to Embodiment 2. The second control unit 307 shown in FIG. 4 is configured to receive configuration data 401 and its valid flag 402, which are signals output from the first control unit 304, and a comparison result 403 obtained from the comparing unit 308, and to output configuration data 404 and its valid flag 405 to the reconfigurable core 309.

If the comparison result 403 indicates a match, configuration is carried out. If the comparison result 403 indicates a mismatch, nothing is carried out. In the case where configuration is carried out, the input configuration data 401 is output to the reconfigurable core 309 as the configuration data 404, and the valid flag 405 is simultaneously asserted. In the case where configuration is not carried out, the configuration data 401 is not output as the configuration data 404, and the valid flag 405 is not asserted. Whether to configure the reconfigurable core 309 may be decided using only the signal of valid flag 405 indicating that the configuration data is valid, by allowing the configuration data 401 to pass through the second control unit 307 and to be directly output as the configuration data 404. Further, instead of deciding whether to perform configuration by using the second control unit 307, whether to operate a circuit actually configured in the reconfigurable core 309 may be decided. Moreover, in this example, whether to configure the reconfigurable core 309 is decided according to the comparison result 403 which indicates a match. However, it may also be decided according to the comparison result 403 which indicates a mismatch, or according to the comparison result 403 which indicates that one of the output of the first storing unit 305 and the output of the second storing unit 306 is greater than, smaller than, equal to or greater than, or equal to or smaller than the other.

FIG. 5 shows another configuration of the second control unit 307 according to Embodiment 2. In the embodiment of FIG. 4, control is performed using configuration data and its valid flag, but in FIG. 5, control is performed using a control signal other than the configuration data and its valid flag. In the case where the control signal 406 is a reset signal for the reconfigurable core 309, the reset signal (406) is canceled if the comparison result 403 indicates a match, and the reset signal (406) is asserted if the comparison result 403 indicates a mismatch. The example in which the comparison result 403 indicates a match/mismatch has been described. However, the logic of the match/mismatch may be inverted, or the comparison result 403 may indicate that one of the output of the first storing unit 305 and the output of the second storing unit 306 is greater than, smaller than, equal to or greater than, or equal to or smaller than the other. Further, the example in which the control signal 406 is a reset signal has been described. However, the control signal 406 may also be a clock enable signal for the reconfigurable core, or a mode signal which determines whether to operate a configured circuit.

According to the invention in Embodiment 2, accompanying information of the user-desired configuration data is stored in the second storing unit 306, and thereby, configuration of the reconfigurable core 309 using configuration data other than the user-desired configuration data, or operation of a circuit configured using the configuration data other than the user-desired configuration data can be prevented.

### Embodiment 3

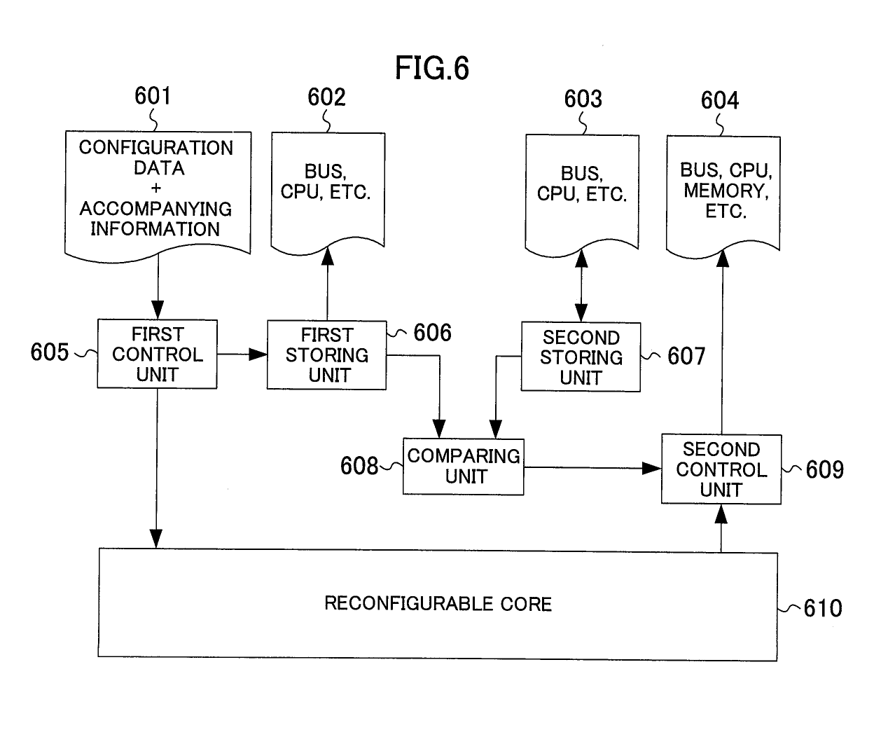

FIG. 6 shows a configuration of a reconfigurable device according to Embodiment 3. The device of FIG. 6 includes: a first control unit 605 for receiving configuration data and its accompanying information (for example, version information and date and time of an update) 601; a first storing unit 606 for receiving and holding the accompanying information output from the first control unit 605; a second storing unit 607 for holding expected value information, which is set by a user or a system in which the device of the present invention is included; a comparing unit 608 for receiving and comparing an output of the first storing unit 606 and an output of the second storing unit 607; a reconfigurable core 610 for receiving the configuration data output from the first control unit 605; and a second control unit 609 for receiving a comparison result of the comparing unit 608 and read-back data from the reconfigurable core 610. The second storing unit 607 is connected to a device 603 such as a CPU directly or via a bus, etc., and therefore can be accessed. Further, the output of the second control unit 609 is sent to a device 604, such as a CPU and a memory, directly or via a bus, etc. The first storing unit 606 is illustrated as being connected to a device 602 such as a CPU directly or via a bus, etc. However, the first storing unit 606 may not be connected to the device 602.

The second control unit 609 is configured to decide whether or not to read back data from the reconfigurable core 610 based on a result of comparison between part or all of the accompanying information of the data configured in the reconfigurable core 610 (i.e., data stored in the first storing unit 606) and part or all of the data set by the user (i.e., data stored in the second storing unit 607).

According to the invention of Embodiment 3, the output of read-back data which is unintended by the user can be avoided.

### <<Configuration Data and Accompanying Information Used in Embodiments 1-3>>

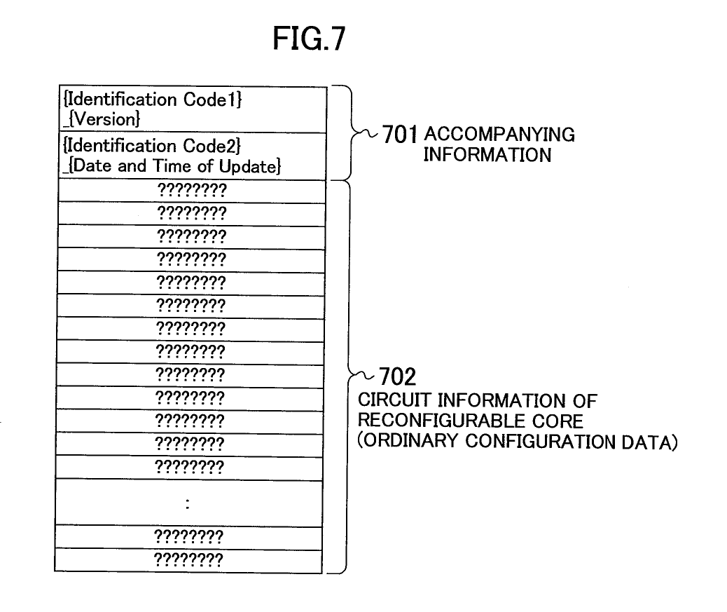

FIG. 7 shows a structure of configuration data and accompanying information used in Embodiments 1-3. The example of FIG. 7 includes accompanying information 701 in which an identification code indicating version information and the version information itself are expressed by one word and in which an identification code indicating date and time of an update and the date and time of an update itself are expressed by one word, and includes configuration data 702 for a reconfigurable core. In FIG. 7, the accompanying information includes two types of information, i.e., version information and date and time of an update, but the number is not limited to two as long as the accompanying information includes one or more types of accompanying information and their respective identification codes. Further, in FIG. 7, the accompanying information is inserted at the top of the configuration data, but may be inserted at the end or in the middle of the configuration data. Moreover, although the version information and the date and time of an update are inserted together, the structure may be such that the version information is inserted at the top of the configuration data and the date and time of an update is inserted at the end of the configuration data.

This enables the first control units 102, 304 and 605 described in Embodiments 1-3 to detect an identification code from the configuration data and the accompanying information in the above-described structure, and thereby the accompanying information and the configuration data can be separated from each other.

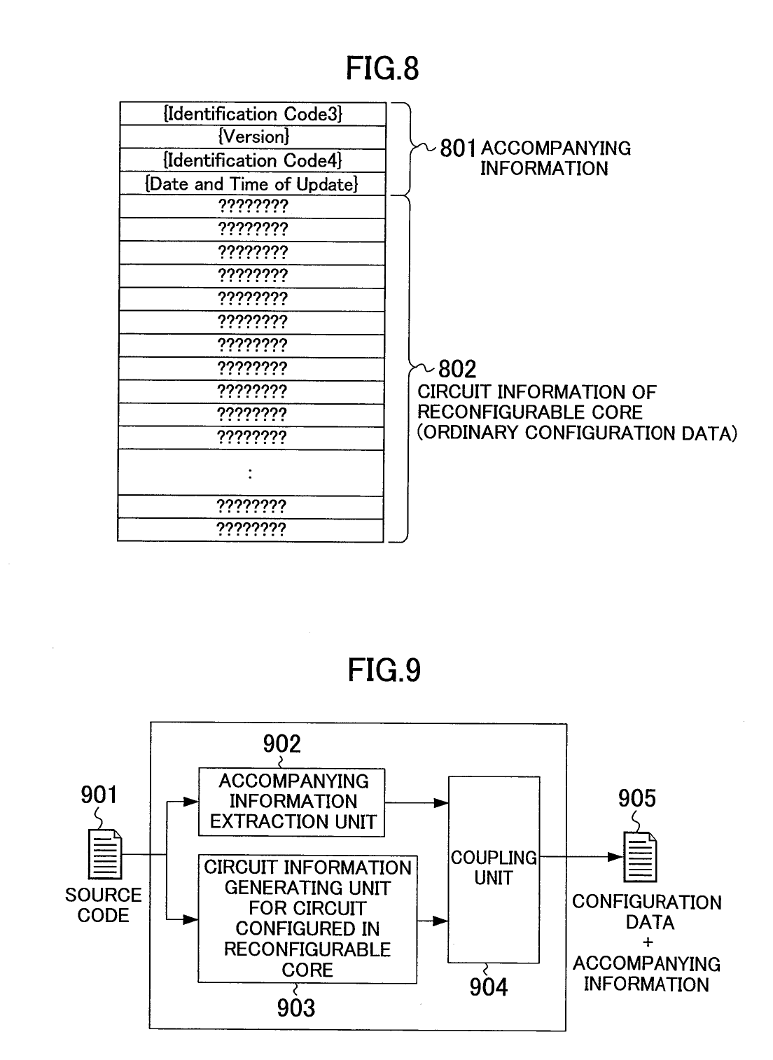

FIG. 8 shows another structure of the configuration data and accompanying information used in Embodiments 1-3. The example of FIG. 8 too is constituted by accompanying information 801 and configuration data 802. A difference between FIG. 7 and FIG. 8 is that an identification code and accompanying information are expressed by different words in FIG. 8. If the accompanying information and its identification code (e.g., identification code 3 and Version in FIG. 8) are considered to be a couple, description is the same as the description for FIG. 7. In FIG. 8, accompanying information subsequent to an identification code is written in one line. However, the accompanying information may be data in two or more lines.

FIG. 9 shows a method for automatically generating the configuration data and accompanying information used in Embodiments 1-3. The example of FIG. 9 includes a source code 901 in which an identifier and version information are written in a comment, “About a circuit to be configured in a reconfigurable core.” The example of FIG. 9 is constituted by an accompanying information extraction unit 902 for extracting accompanying information from a time stamp, version information of the comment, etc., of the source code 901, a circuit information generating unit 903 for forming configuration data of a circuit to be configured in a reconfigurable core, and a coupling unit 904 for receiving output results from the accompanying information extraction unit 902 and the circuit information generating unit 903.

The identifier of the above comment is detected to extract version information from the source code 901. Information concerning date and time of an update is extracted by reading a time stamp of a source code file. Other methods include, if the source code is controlled by a version control system such as Concurrent Versions System (CVS), extracting accompanying information by sending an inquiry to the version control system. Also, information (e.g., name, current time, etc.) of a computer which generates configuration data and accompanying information may be used as accompanying information.

By these methods, data 905 in which the configuration data and accompanying information are combined can be automatically formed.

### Embodiment 4

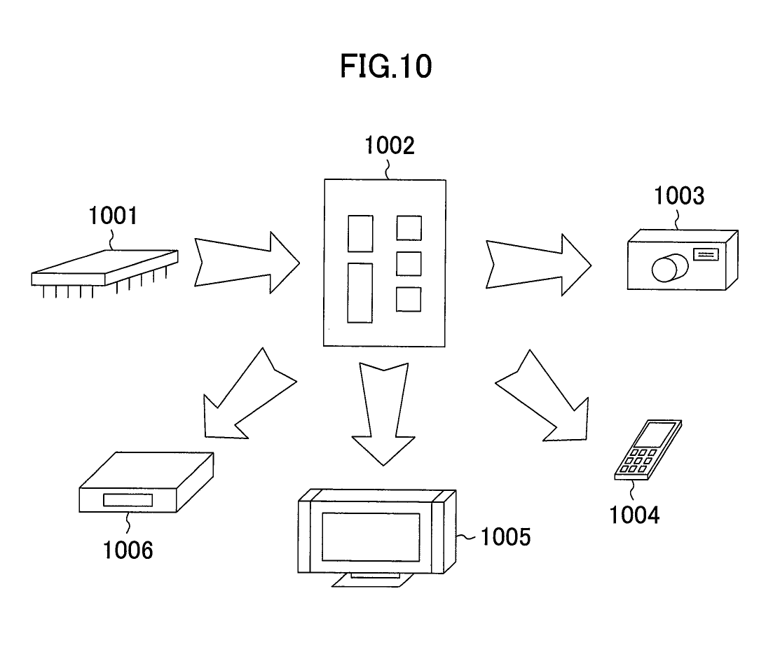

FIG. 10 shows an example of a system using the reconfigurable devices of Embodiments 1-3, and configuration data and accompanying information used in the reconfigurable devices. The reconfigurable device 1001 according to any one of Embodiments 1-3 can be applied in a camera 1003, a mobile phone 1004, a television system 1005, a recorder 1006, etc., via a board 1002 on which an LSI (Large Scale Integrated Circuit) is mounted.

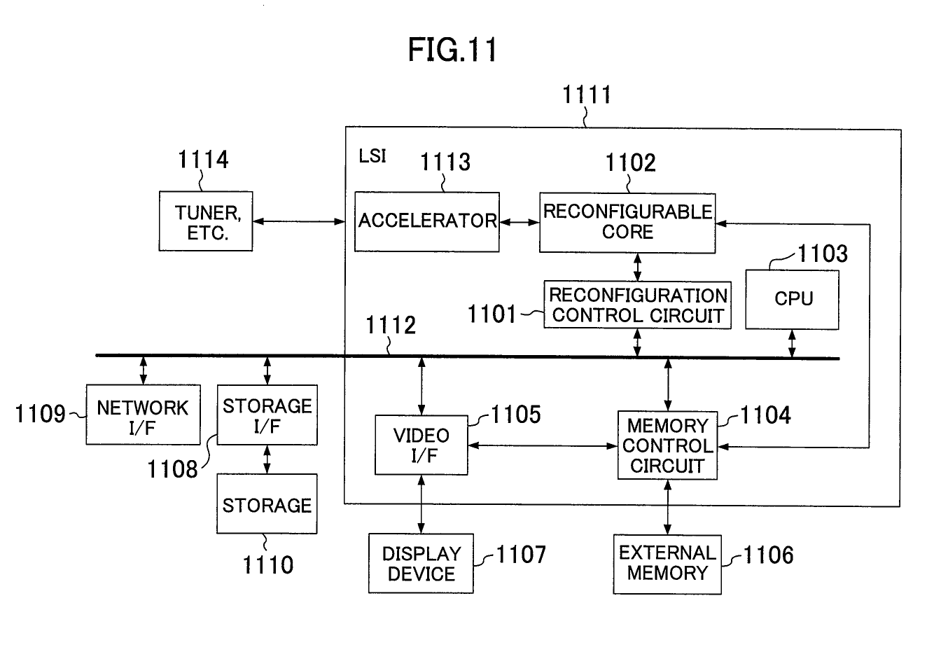

FIG. 11 shows a configuration of a digital television system including the reconfigurable device according to Embodiment 1. The system LSI 1111, which is a reconfigurable device, is constituted by a reconfigurable core 1102, a control circuit 1101 for the reconfigurable core 1102, an accelerator 1113 which operates in coordination with the reconfigurable core or performs a different processing, a memory control circuit 1104 which interacts with an external memory, a CPU 1103, a video I/F (interface) 1105 which outputs a signal to a display, and a bus 1112 which connects these devices. An external memory 1106 (e.g., Double Data Rate Synchronous Dynamic Access Memory (DDR SDRAM)), a display device 1107, a storage I/F 1108, a network I/F 1109, and a unit 1114, such as a tuner, for demodulating a signal from an antenna are connected to the system LSI 1111 via a board, etc. A storage 1110 (e.g., a hard disk drive) is connected to the storage I/F 1108.

In the configuration of FIG. 11, a tuner, etc., 1114 first receives a video signal from an antenna, and modulates the video signal. The accelerator 1113 and the reconfigurable core 1102 decode the encoded video signal, and the result is stored in the external memory 1106. Lastly the data is transmitted from the video I/F 1105 to the display device 1107 to show the video. The CPU 1103 obtains accompanying information relating to configuration data stored in the reconfiguration control circuit 1101, and has the function of comparing the obtained accompanying information with accompanying information of configuration data located at a predetermined location through the network I/F 1109 to automatically obtain more appropriate configuration data and update the reconfigurable core 1102.

According to Embodiment 4 shown in FIG. 11, adjustment of image quality, addition of a codec capable of playback, and so on, can be automatically or manually performed within a range that can be performed by the reconfigurable core, even after the shipment of the system as long as the system can be connected to a network.

Although the system LSI 1111 is described as including an accelerator, a reconfigurable core, reconfiguration control circuit, a CPU, a memory control circuit, a video I/F and a bus, the system LSI 1111 may include other function blocks, and some of the function blocks may be provided on a different chip. Also, although the CPU is used as comparison means, the comparison means does not have to be a CPU as long as it has a comparison function.

A system using the reconfigurable device according to Embodiment 1 has been described. However, any one of the reconfigurable devices according to Embodiments 1-3 may be used.

A digital television system has been described. However, the present invention can, of course, be applied to mobile phones, recorders, video cameras, still cameras, vehicle-mounted equipment, and so on.

In the above example, configuration data has been obtained from a network. However, the configuration data may be obtained from a storage, such as a hard disk and a flash memory.

### INDUSTRIAL APPLICABILITY

As described in the above, the present invention is useful in using reconfigurable devices, as represented by FPGAs, in a system.

1. A reconfigurable circuit device, comprising:
a first control unit for outputting configuration data and accompanying information;
a first storing unit for receiving and storing the accompanying information; and
a reconfigurable core for receiving the configuration data and reconfiguring a circuit.

2. A reconfigurable circuit device, comprising:
a first control unit for outputting configuration data and accompanying information;
a first storing unit for receiving and storing the accompanying information;
a second storing unit for receiving and storing expected value information;
a first comparing unit for comparing an output of the first storing unit and an output of the second storing unit;
a second control unit for receiving an output of the first comparing unit and determining an execution of a reconfiguration based on the output of the first comparing unit; and
a reconfigurable core for receiving an output of the second control unit and reconfiguring a circuit.

3. A reconfigurable circuit device, comprising:
a first control unit for outputting configuration data and accompanying information;
a first storing unit for receiving and storing the accompanying information;
a second storing unit for receiving and storing expected value information;
a first comparing unit for comparing an output of the first storing unit and an output of the second storing unit;
a second control unit for receiving an output of the first comparing unit and determining an execution of a read-back operation from a reconfigurable core based on the output of the first comparing unit; and
a reconfigurable core for receiving the configuration data, reconfiguring a circuit, and having a read-back function.

4. The reconfigurable circuit device of claim 1, wherein
the accompanying information includes an identification code, and
the first control unit detects the identification code.

5. A receiving apparatus, comprising:
a reconfigurable circuit device of claim 1; and
a configuration in which configuration data and accompanying information both on a network are obtained, wherein
the reconfigurable circuit device further includes a second comparing unit for comparing accompanying information of configuration data in the reconfigurable circuit device and the accompanying information of the configuration data on the network, and
the configuration data in the reconfigurable circuit device is updated according to a result of the comparison by the second comparing unit.

6. A receiving apparatus, comprising:
a reconfigurable circuit device of claim 1; and
a storage device connected to the reconfigurable circuit device and having configuration data and accompanying information, wherein
the reconfigurable circuit device further includes a second comparing unit for comparing accompanying information of configuration data in the reconfigurable circuit device and the accompanying information of the configuration data stored in the storage device, and
the configuration data in the reconfigurable circuit device is updated according to a result of the comparison by the second comparing unit.
